(19) United States
(12) Patent Application Publication
(10) Pub. No.: US 2021/0242429 A1
(43) Pub. Date: Aug. 5, 2021

(54) COATING SOLUTION FOR LIGHT EXTRACTION LAYER OF ORGANIC LIGHT-EMITTING DEVICE AND METHOD OF MANUFACTURING LIGHT EXTRACTION SUBSTRATE OF ORGANIC LIGHT-EMITTING DEVICE BY USING THE SAME

(71) Applicant: CORNING INCORPORATED, CORNING, NY (US)

(72) Inventor: JooYoung Lee, Asan-si (KR)

(21) Appl. No.: 17/054,302

(22) PCT Filed: May 14, 2019
(86) PCT No.: PCT/US2019/032243

§ 371 Date: Nov. 10, 2020

(30) Foreign Application Priority Data
May 15, 2018 (KR) 10-2018-0055478

(51) Int. Cl. H01L 51/52; C09D 1/00; C09D 7/20

(52) U.S. Cl. CPC H01L 51/5268; C09D 7/20; C09D 1/00

(57) ABSTRACT

A coating solution for a light extraction layer of an organic light-emitting device may include light-scattering particles including a metal oxide; and a solvent. A method of manufacturing a light extraction substrate of an organic light-emitting device can form a light extraction layer on a base substrate, by inkjet coating or spray coating, using the coating solution.

### CROSS-REFERENCE TO RELATED APPLICATIONS

This application is based upon and claims the benefit of priority from prior Korean patent application No. 10-2018-0055478 filed on May 15, 2018, the entire contents of which are incorporated herein by reference.

### TECHNICAL FIELD

The present disclosure relates to a coating solution for a light extraction layer of an organic light-emitting device and a method of manufacturing a light extraction substrate of an organic light-emitting device using the same.

### BACKGRAOUND ART

As interests in light extraction efficiency of an organic light-emitting device are increasing, researches on an internal or external light extraction layer have been actively conducted. Since only about 20% of total generated light is emitted to an outside, researches on a light extraction layer are conducted so as to extract and use 80% of the light, which is lost in an optical waveguide mode, from the organic light-emitting device. The light extraction layer is largely divided into internal and external light extraction layers. The external light extraction layer can achieve effects by attaching a film, which includes microlenses of diverse forms, to the outside of a base substrate, and its light extraction efficiency does not much depend on the forms of the microlenses. The internal light extraction layer extracting the light which is lost in the optical waveguide mode can attain a higher light extraction efficiency than the external light extraction layer. When the internal light extraction layer is formed with a mixture of materials having different refractive indices, it is possible to maximize a light-scattering effect. To this end, however, light-scattering structures having sizes that can be recognized by the light should be mixed. The light-scattering structures of diverse forms (shapes of particles, shapes of pores, and the like) and diverse materials may be utilized.

### SUMMARY OF INVENTION

Aspect of non-limiting embodiments of the present disclosure relates to a coating solution for coating a light-scattering layer capable of extracting the lost light and a method of manufacturing a light extraction substrate.

Aspects of certain non-limiting embodiments of the present disclosure address the features discussed above and/or other features not described above. However, aspects of the non-limiting embodiments are not required to address the above features, and aspects of the non-limiting embodiments of the present disclosure may not address features described above.

According to a first aspect of the present disclosure, there is provided a coating solution for a light extraction layer of an organic light-emitting device. The coating solution includes light-scattering particles, which include a metal oxide, and a solvent.

According to a second aspect of the present disclosure, there is provided a method of manufacturing a light extraction substrate of an organic light-emitting device. The method includes forming a light extraction layer on a base substrate using the coating solution for a light extraction layer of an organic light-emitting device.

### BRIEF DESCRIPTION OF DRAWINGS

Embodiment(s) of the present disclosure will be described in detail based on the following figures, wherein:

FIG. 1 is a cross-sectional view depicting a structure of an organic light-emitting device in accordance with an embodiment of the present disclosure.

FIG. 2 is a view sequentially depicting a process of spraying and coating a base substrate with liquid drops of a coating solution.

FIG. 3 is a view depicting an edge profile of a coating layer.

FIG. 4 is a plan view of the coating layer.

FIG. 5 is a measurement result showing the edge profile of the coating layer.

FIG. 6 is a graph showing a simulation result of Haze intensity by light-scattering structures, which are pores, in a matrix of a high refractive metal oxide with respect to representative wavelengths (400 nm, 550 nm and 660 nm).

FIG. 7 is a view showing a coffee ring generated at an edge of a coating layer in Comparative Example.

FIG. 8 is a view showing solution stability of the coating solution in accordance with an embodiment of the present disclosure.

FIG. 9 is a view showing surface tension of the coating solution in accordance with an embodiment of the present disclosure.

FIG. 10 is a view showing results of inkjet coating depending on viscosities of the coating solution.

FIG. 11 is a graph showing a result obtained by measuring the viscosity of the coating solution in accordance with an embodiment of the present disclosure while changing a shear rate.

FIG. 12 is a view showing a light extraction substrate manufactured in accordance with an embodiment of the present disclosure.

### DESCRIPTION OF EMBODIMENTS

Hereinafter, the present disclosure will be described in detail with reference to the accompanying drawings.

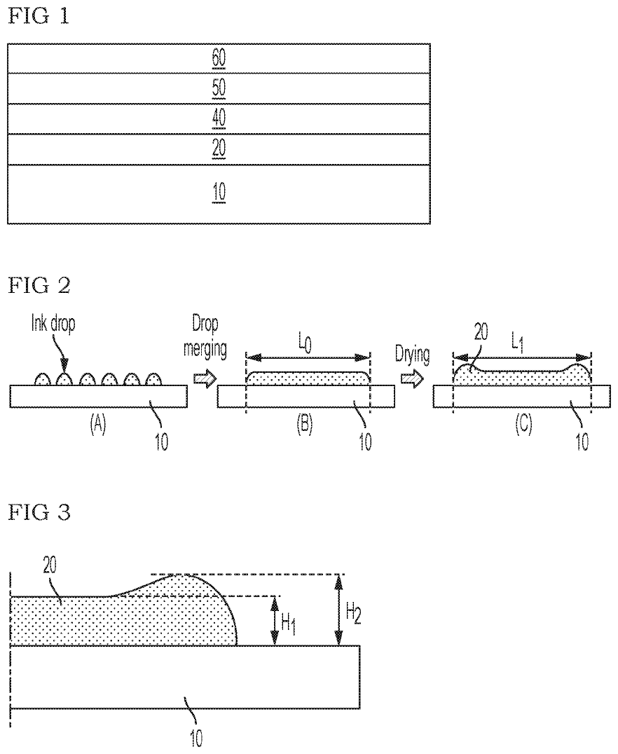

FIG. 1 is a cross-sectional view depicting a structure of an organic light-emitting device in accordance with an embodiment of the present disclosure.

In an embodiment, as shown in FIG. 1, the organic light-emitting device may include a light extraction substrate and an organic light-emitting element formed on the light extraction substrate. In an embodiment, the light extraction substrate may include a base substrate 10, and a light extraction layer formed on the base substrate 10. In an embodiment, the light extraction layer may include a light-scattering layer 20. The organic light-emitting element may include electrode layers 40, 60 and an organic layer 50. The organic layer 50 may include a light-emitting layer. In an embodiment, the light extraction layer may include a planarization layer (not shown) formed between the light-scattering layer 20 and the electrode layer 40, in addition to the light-scattering layer 20. When electric energy is supplied to the organic layer 50 through the electrode layers 40, 60, light is generated in the light-emitting layer of the organic layer 50, and the generated light sequentially passes through the electrode layer 40, the light-scattering layer 20 and the base substrate 10, and is then emitted to an outside.

For the base substrate 10, any transparent material such as glass, plastic and the like may be used. The base substrate 10 may be manufactured, using such material, by a roll-to-roll manufacturing method, for mass production.

In order to coat the base substrate 10 with the light-scattering layer 20, a liquid type coating material may be favorable. For the service life of the organic light-emitting device, it is necessary to locate the light-scattering layer 20 in encapsulation of the organic light-emitting device so as to prevent moisture and oxygen from being infiltrated from the outside. In this case, the light-scattering layer 20 is necessarily adjusted to have a specific shape (a circular shape, a quadrangular shape and the like), in conformity to a shape of the organic light-emitting device (or a shape of the organic layer). To this end, a method of coating an entire surface of the base substrate 10 by bar coating, slot die coating or the like and then, removing a coating layer on a part corresponding to the outside of the organic layer or a method of selectively coating only a part corresponding to the organic layer by inkjet coating, spray coating or the like may be used. When using the inkjet coating or the spray coating, the light-scattering particles dispersed in the liquid are jetted or sprayed. The liquid coating solution jetted in forms of liquid drops from nozzles is evaporated while it moves to reach the base substrate 10. When solids such as light-scattering particles are included, the evaporation may be further accelerated. The reason is that a volume of a single liquid drop is very small, for example, of several picoliters to several tens of picoliters (picoliter: 1×10⁻¹² L). Therefore, it is necessarily required to manufacture a coating solution suitable for a coating method. In particular, in the cases of the inkjet coating and the spray coating, it is necessary to provide an optimal coating solution so as to obtain an excellent coating quality without clogging the nozzles.

When extracting the light produced in the organic light-emitting element, it is preferably to use a method of using refraction by a difference of refractive indices, which can reduce the light loss. In this case, light-scattering particles having appropriate sizes may be used for efficient light scattering. The light-scattering particles may include at least one of a metal oxide such as TiO₂, BaTiO₃, ZnO, MgO, SnO₂, Al₂O₃, ZrO₂, CeO₂, Fe₂O₃, Fe₃O₄, WO₃, Y₂O₃, SrTiO₃, FeTiO₃, MnTiO₃, Nb₂O₅, KTaO₃ and the like, and SiO₂.

The particles are dispersed in a solvent to manufacture a liquid coating solution that is to be used for coating. As described above, for the selective coating in a liquid drop form, the volatility of the solvent in which the light-scattering structures are to be dispersed is very important. When the solvent does not have the appropriate volatility, a quality of the coating is considerably lowered or the coating cannot be performed because the nozzles are clogged. In an embodiment of the present disclosure, the solvent may include at least one selected from the group consisting of butyl cellosolve, diacetone alcohol, dipropylene glycol methyl ether, a-terpineol, benzyl alcohol, dodecane, formamide, ethyl-3-ethoxypropionate, N-methyl-2-pyrollidone, diethylene glycol monomethyl ether siloxane, silsesquioxane, silazane, a siloxane derivative, a silsesquioxane derivative, a silazane deriavative and the like.

In an embodiment, considering physical properties, a weight of the light-scattering particles may not exceed 50% of a total weight of the coating solution after foreign matters are removed through filtering. When the ratio of the light-scattering particles is too great, the clogging of the inkjet nozzles is accelerated, which makes it difficult to obtain the high-quality coating.

Even when the light-scattering particles in an appropriate weight ratio and the solvent having the appropriate volatility are used, the coating is impossible unless the light-scattering particles are appropriately dispersed in the solvent to form a stable dispersant solution. Therefore, an appropriate dispersant (surfactant) may be added. In an embodiment, the dispersant may include at least one selected from the group consisting of alkylammonium salt of polymer, polyether phosphate, polyethylene glycol octylphenyl ether, poly(ethylene oxide), secondary alcohol ethoxylate, acrylate polymer, 2-(dibutylamino)ethanol, or a mixture thereof. Such materials can contribute to formation of the very stable coating layer after 99.5% or more of the volatile material is volatilized when the coating solution is subjected to a temperature of 440° C. An amount of the dispersant may be proportional to surface areas of the light-scattering particles. In an embodiment, when the light-scattering particles of the metal oxides are used, the amount of the dispersant may not exceed 15% of a weight of the light-scattering particles. The reason is that the surplus dispersant or surfactant not bound with the surfaces of the light-scattering particles may deteriorate the stability of the coating solution and may be outgassed after a long time from the manufacturing of the organic light-emitting device, thereby shortening the service life of the organic light-emitting device.

In the case of the inkjet coating or spray coating, the liquid drops are jetted. At this time, the liquid drops should be designed to have optimal wettability on the base substrate 10. If not, the liquid drops are not merged in a B step of FIG. 2, so that it is difficult to make a smooth coating surface. This has close relation to a contact angle or surface tension of the coating solution. When a horizontal length of the coating surface coated at an early stage is denoted as L₀ and a horizontal length of the coating surface after drying is denoted as L₁, a relation of L₁>L₀ is usually satisfied due to the wettability of the liquid drops. In this case, it is easy to control the coating quality when the liquid drops are smoothly merged and the length Li is not excessively greater than the length L₀. For example, when the length L₀ is 80mm, the length can be controlled to Li<81.5mm by using the coating solution in accordance with an embodiment of the present disclosure (a rate of increase in the longitudinal direction is less than 1.9%). In general, it is possible to make a solution capable of satisfying a relation of L₁/L₀<1.1.

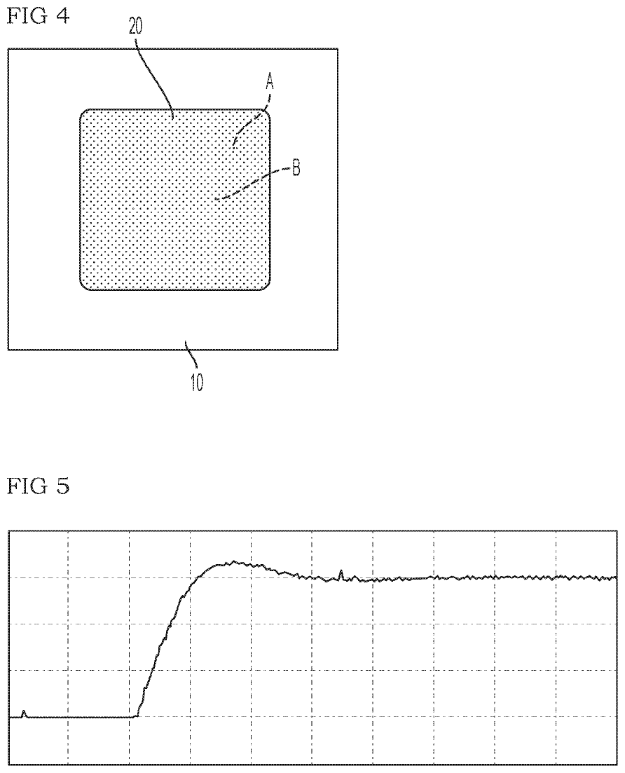

While the coating solution is applied and then, dried, diverse phenomena occur. For example, as shown in C of FIG. 2, a phenomenon that ends of the coating rise up like hills occurs. This means H₂>H₁ when a height of a central surface of the coating layer is denoted as Hi and a height of the hill is denoted as H₂ (refer to FIG. 3). When the height H₂ is excessively higher than the height H₁, a probability that disconnection and appearance defect will occur is high. This phenomenon commonly occurs at the edge portions of all the coating layers (a cross section B in FIG. 4), and becomes particularly severe when forming a polygonal coating layer (a cross section A in FIG. 4).

When the coating is formed in the shape of FIG. 4 and the cross sections A, B are measured by a surface profiler (DekTak available from BRUKER Company), a profile as shown in FIG. 5 can be obtained. At this time, a ratio of the heights H₁, H₂ may be H₂/H₁<5. In an embodiment, an angle between a horizontal plane and the coating surface may be about 10° or smaller, about 2° or smaller or about 0.5° or smaller. FIG. 5 shows an example where the angle between the horizontal plane and the coating surface is about 3°.

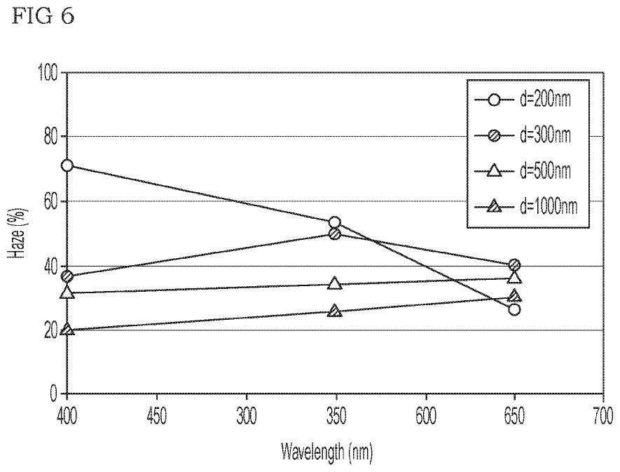

Usually, with regard to the inkjet or spray coating, the light-scattering particles of the metal oxide may have a bad influence on the nozzles. Therefore, it is preferably to use the particles having sizes as small as possible. However, since particles of several tens of nanometers or smaller have negligible light-scattering properties, the effectiveness of the inkjet solution using the particles is inevitably deteriorated. However, the present disclosure can maximize the light-scattering properties even with the particles of 20 nm to 50 nm. This can be seen from a simulation result of FIG. 6. When the coating solution according to an embodiment of the present disclosure is used, it is possible to form pores of diverse sizes, for example, pores of several tens of nanometers to hundreds of nanometers, so that it is possible to induce formation of light-scattering structures, which are effective pores. FIG. 6 is a graph showing a simulation result of Haze intensity by the light-scattering structures, which are pores, in a matrix of a high refractive metal oxide with respect to representative wavelengths (400 nm, 550 nm and 660 nm), when an average size of the light-scattering structures is used as a variable and a ratio of the light-scattering structures is about 11% of a cross sectional area of the coating layer, in accordance with an FDTD method. As can be seen from the graph, as the sizes of the light-scattering structures, which are pores, become smaller on the basis of d=1000 nm, the Haze intensity increases. Considering that a normal organic light-emitting device exhibits low intensity of blue, it can be seen that the light-scattering structures of d=200 nm or smaller, which exhibit the higher Haze intensity around the wavelength of 400 nm, may be preferable. Therefore, the method of forming pores by using the very small particles (20 nm to 50 nm) as disclosed in the present disclosure, can play a great role in keeping the durability of the inkjet and spray coating nozzles while increasing the light scattering efficiency.

In general, it is preferable that a surface of the light extraction layer is smooth. The reason is that this is helpful in forming the electrode layer on the light extraction layer and then, vapor-depositing the organic layer thereon. On the contrary, when the surface of the light extraction layer is rough, disconnection in an electrode occurs or a hot spot is created to cause a defect due to heat generation. Therefore, as described above, when the light-scattering particles having an average particle diameter of about 20 nm to 50 nm are used, the surface of the light extraction layer is glossy after the drying, like a reflector. This indicates that the surface is formed, as intended.

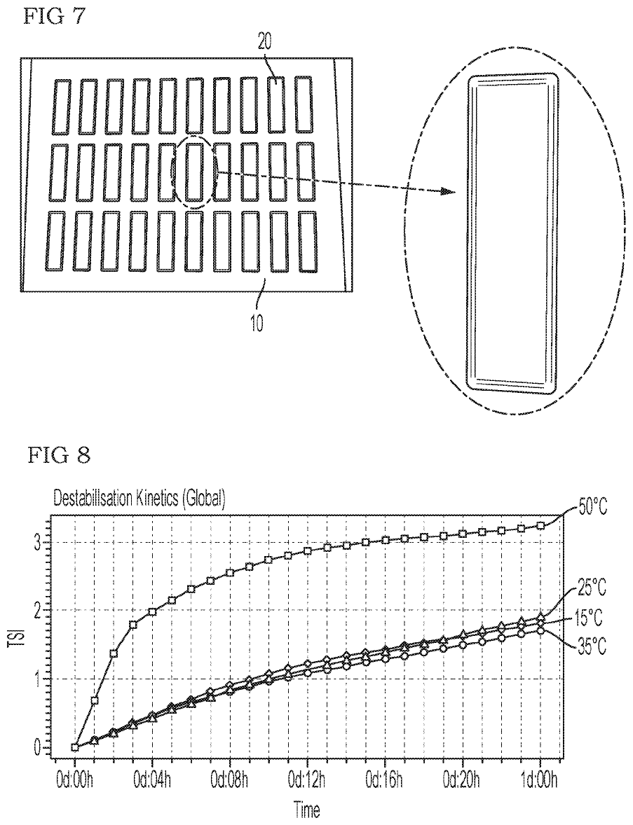

When a coating solution prepared using the light-scattering particles having large particle diameters is coated by the inkjet, a non-uniform line can be seen at a boundary between the inside and the outside of the coating layer, as shown in FIG. 7. This is not favorable because the light may be non-uniformly extracted. A coffee ring is created at the edge of the coating layer, which indicates that the edge profile is very poor. Also, when the light-scattering particles having large particle diameters are used, the nozzles are frequently clogged, which may significantly lower the productivity of the coating operation.

The coating solution is applied and then, heated to temperatures of 440° C. or higher. This serves to minimize outgassing of the light extraction layer when manufacturing the organic light-emitting device, which is very helpful for the service life of the organic light-emitting device. In addition, it is preferable to remove organic components such as a binder and the like left in the light extraction layer by the high-temperature heating because the organic components increase the light absorptivity of the light extraction layer to deteriorate the efficiency.

FIG. 8 is a view showing stability of the coating solution in accordance with an embodiment of the present disclosure.

In the embodiment, the stability (TSI; Turbiscan Stability Index) of the coating solution may be 30 or less or 3 or less when measured over 24 hours. The stability (TSI) can be measured using a Turbiscan (available from Formulaction Company) configured to measure the stability by using an amount of change in backscattering when the solution is allowed to be stationary.

$$TSI = \sqrt{\frac{{\sum }_{i = 1}^{n} {( {x}_{i} - {x}_{BS} )}^{2}}{n - 1}}$$

(xᵢ: average backscattering value measured in a specific time zone,

x_{BS}: average of xᵢ, n: the number of scanning times)

In the embodiment shown in FIG. 8, the TSI was about 2.0 or less at 15° C. to 35° C. and about 3.2 at 50° C. when measured over 24 hours. Considering the rapid precipitation at high temperatures, it can be seen that it is possible to manufacture the very stable coating solution.

It is not common for the usual inkjet ink to include nano-particles. However, the coating solution in accordance with the embodiment of the present disclosure includes the nano-particles, so that the stability is very important. In the case of a coating solution having poor stability, the light-scattering particles dispersed in the solution are rapidly precipitated. This may cause the concentration of the solution discharged from a nozzle to be non-uniform or cause the nozzles to be clogged.

FIG. 9 is a view showing surface tension of the coating solution in accordance with an embodiment of the present disclosure.

In the embodiment, a surface tension of the coating solution may be 10 dyne/cm to 70 dyne/cm, 27 dyn/cm to 45 dyn/cm or 32 dyn/cm to 45 dyn/cm. The coating solution having such surface tension in accordance with the embodiment of the present disclosure can be discharged in a correct direction from the nozzles and can be thus printed in a desired shape on a substrate.

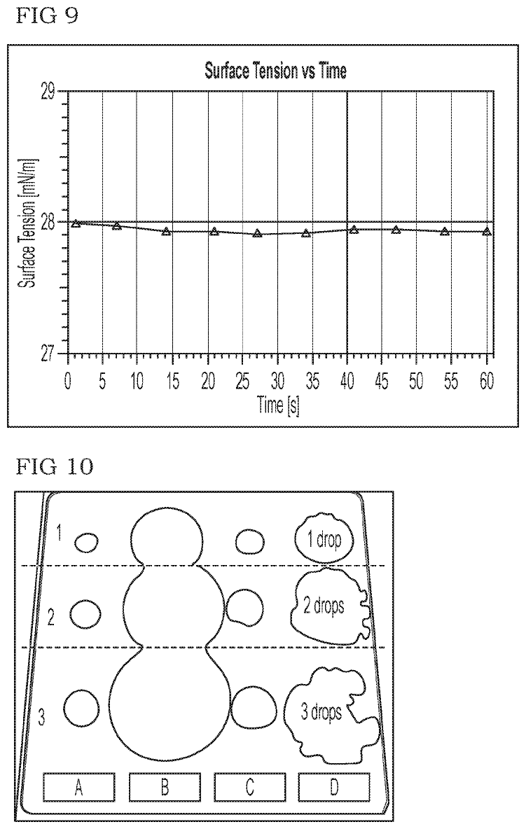

FIG. 10 is a view showing results of the inkjet coating depending on viscosities of the coating solution.

A viscosity of the coating solution to be used for the inkjet coating may be 0.1 cp to 20 cp or 5 cp to 15 cp.

Referring to FIG. 10, the viscosities of the coating solutions A, C were 5 cp to 6 cp, and the viscosities of the coating solutions B, D were 2 cp to 3 cp. The spreading degrees were different when the same amount of the coating solution was dropped. Although the coating with the coating solutions B, D was not impossible, the better coating result was obtained by the coating solutions A, C.

### TEST EXAMPLE 1

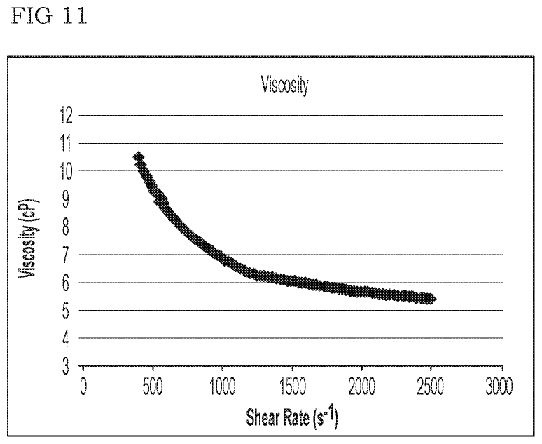

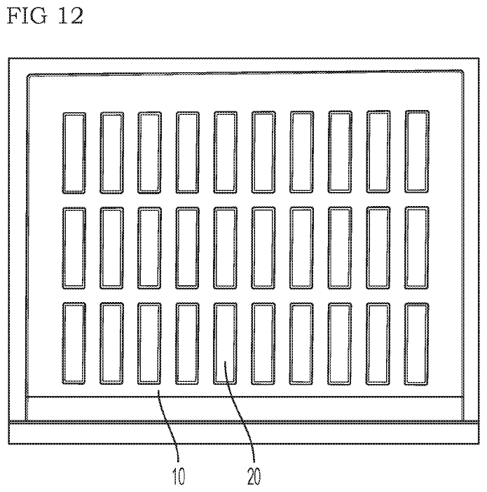

1.48 g of alkylammonium salt of acidic polymer was added to 210 g of dipropylene glycol monomethyl ether (or diacetone alcohol), and then, the resultant mixture was stirred well. Then, 37 g of rutile TiO₂ powders (average particle size=20 nm to 50 nm) were added to the mixture, which was again stirred and dispersed for one hour with an ultrasonic processor of 350 W and 20 kHz. The impurities of the dispersion solution were filtered using an appropriate filter, so that a coating solution was obtained. A result obtained by measuring the viscosity of the coating solution while changing the shear rate is shown in FIG. 11. For the measurement, Haake viscotester 550 was used. The viscosity of 5 cp to 15 cp was observed in the range of 500/s to 2500/s. From this, it could be seen that the coating solution has a shear thinning characteristic. The coating solution has a very advantageous viscosity behavior because the high shear stress is instantaneously applied to the coating solution at the ends of the nozzles when the coating solution is used for the inkjet printing, the spray coating and the like. With the inkjet coater, the coating solution was coated on the glass base substrate 10, so that the light-scattering layers 20 as shown in FIG. 12 were obtained. After vapor-depositing ITO electrode layers on the light-scattering layers 20, an organic layer was formed to manufacture an organic light-emitting device. With the organic light-emitting device, the light extraction efficiency of 1.6 times or more was obtained.

### TEST EXAMPLE 2

0.4 g of alkylammonium salt was added and mixed well with 26 g of diacetone alcohol. 8 g (23.3wt%) of BaTiO₃ powders were added to the mixture, which was then treated for about 18 minutes with the ultrasonic processor of 300 W and 20 kHz. The impurities were removed using a glass micro fiber filter, and the inkjet coating was then performed to form a light-scattering layer. The light-scattering layer was particularly suitable for extraction of the light of long wavelengths because it sensitively responded to the light of long wavelengths due to particularly high transmittance and Haze intensity. The light extraction efficiency of 1.5 times or more was obtained by the organic light-emitting device.

The foregoing description of the embodiments of the present disclosure has been provided for the purposes of illustration and description. It is not intended to be exhaustive or to limit the present disclosure to the precise forms disclosed. Obviously, many modifications and variations will be apparent to one skilled in the art. The embodiments were chosen and described in order to best explain the principles of the present disclosure and its practical applications, thereby enabling others skilled in the art to understand the present disclosure for various embodiments and with the various modifications as are suited to the particular use contemplated. It is intended that the scope of the present disclosure be defined by the following claims and their equivalents.

What is claimed is:

1. A coating solution for a light extraction layer of an organic light-emitting device, the coating solution comprising:
light-scattering particles comprising at least one of a metal oxide and SiO₂; and
a solvent,
wherein the coating solution has a turbiscan stability index (TSI) of 30 or less when measured over 24 hours.

2. The coating solution according to claim 1, wherein the metal oxide comprises at least one selected from the group consisting of TiO₂, SiO₂, BaTiO₃, ZnO, MgO, SnO₂, Al₂O₃, ZrO₂, CeO₂, Fe₂O₃, Fe₃O₄, WO₃, Y₂O₃, SrTiO₃, FeTiO₃, MnTiO₃, Nb₂O₅, and KTaO_{3.}

3. The coating solution according to claim 1, wherein the solvent comprises at least one selected from the group consisting of butyl cellosolve, diacetone alcohol, dipropylene glycol methyl ether, a-terpineol, benzyl alcohol, dodecane, formamide, ethyl-3-ethoxypropionate, N-methyl-2-pyrrolidone, diethylene glycol monomethyl ether, siloxane, silsesquioxane, silazane, a siloxane derivative, a silsesquioxane derivative, and a silazane derivative.

4. The coating solution according to claim 1, wherein a weight of the light-scattering particles is 50% or less of a weight of the coating solution.

5. The coating solution according to claim 1, further comprising a dispersant.

6. The coating solution according to claim 5, wherein the dispersant comprises at least one selected from the group consisting of alkylammonium salt of polymer, polyether phosphate, polyethylene glycol octylphenyl ether, poly(ethylene oxide), secondary alcohol ethoxylate, acrylate polymers, and 2-(dibutylamino)ethanol.

7. The coating solution according to claim 5, wherein a weight of the dispersant is 15% or less of a weight of the light-scattering particles.

8. The coating solution according to claim 1, wherein the light-scattering particles have particle sizes ranging from 20 nm to 50 nm.

9. The coating solution according to claim 1, wherein the coating solution has a surface tension ranging from 10 dyne/cm to 70 dyne/cm.

10. The coating solution according to claim 1, wherein the coating solution has a viscosity ranging from 0.1 cp to 20 cp.

11. The coating solution according to claim 10, wherein the coating solution has a viscosity ranging from 5 cp to 15 cp.

12. A method of manufacturing a light extraction substrate of an organic light-emitting device, the method comprising:
forming a light extraction layer on a base substrate by using a coating solution,
wherein the coating solution comprises:
light-scattering particles comprising at least one of a metal oxide and SiO₂; and
a solvent, and
wherein the coating solution has a turbiscan stability index (TSI) of 30 or less when measured over 24 hours.

13. The method according to claim 12, wherein forming the light extraction layer comprises coating the base substrate with the light extraction layer by inkjet coating or spray coating.

14. An apparatus for manufacturing a light extraction substrate of an organic light-emitting device,
wherein the apparatus is configured to form a light extraction layer by coating a base substrate with a coating solution,
wherein the coating solution comprises:
light-scattering particles comprising at least one of a metal oxide and SiO₂; and
a solvent, and
wherein the coating solution has a turbiscan stability index (TSI) of 30 or less when measured over 24 hours.
